(19) United States
(12) Patent Application Publication
(10) Pub. No.: US 2016/0254246 A1
(43) Pub. Date: Sep. 1, 2016

(54) APPARATUS AND METHOD FOR BONDING CHIPS

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Rui LI, Beijing (CN); Young Man KWON, Beijing (CN); Yong SONG, Beijing (CN)

(73) Assignees: BOE Technology Group Co., Ltd., Beijing (CN); Beijing Boe Optoelectronics Technology Co., Ltd., Beijing (CN)

(21) Appl. No.: 14/387,804

(22) PCT Filed: Oct. 12, 2013
(86) PCT No.: PCT/CN2013/085114

§ 371 Date: Sep. 24, 2014

(30) Foreign Application Priority Data
May 21, 2013 (CN) 201310189801.2

(51) Int. Cl. H01L 23/00; H01L 25/065; H01L 25/00

(52) U.S. Cl. CPC H01L 24/83; H01L 24/29; H01L 24/32; H01L 24/75; H01L 25/50; H01L 25/0655; H01L 2224/2929; H01L 2224/32225; H01L 2224/75983; H01L 2224/83192; H01L 2224/83203; H01L 2924/07811; H01L 2924/15788; H01L 2924/3511; H01L 2224/8385; H01L 2924/20105

(57) ABSTRACT

An apparatus and method for bonding chips (4) is disclosed. The apparatus for bonding chips (4) comprises: a base stage (1) and a press head (2), the side of the base stage (1) for carrying the substrates (3) has a first downward concave curvature, the side of the press head (2) contacting with the chips (4) has a second downward convex curvature, and the base stage (1) with the first curvature and the press head (2) with the second curvature match with each other. The warping problem of the bonded chips (4) and substrate (3) can be overcome.

### TECHNICAL FIELD

The embodiments of present invention relate to an apparatus and method for bonding chips.

### BACKGROUND

In order to further reduce of cost, current small-size liquid crystal display products generally drive the liquid crystal display panel by means of chips bonding process of COG (Chip on Glass). Particularly, after raised points are formed on the bare chips, the same is directly wired to the lead of the liquid crystal display on the substrate.

In the COG bonding process, when performing primary pressing, the press head at high temperature first contacts the chips, and transfers heat to the anisotropic conductive adhesive and substrate through the chips. At this time, the substrate and the stage on which the substrate is positioned have a relative large temperature difference, causing a difference between the expansion dimensions of the substrate and the stage. After the curing of the anisotropic conductive adhesive, the relative position of the chips and substrate is fixed. After the primary pressing, during the cooling of the chips and the substrate, the chip may have a larger contraction dimension than the substrate, and thus two ends of the chip may produce a relative large stress acting on the substrate, resulting in a warping in the chips and the substrate. The warping of the chip and substrate may cause the stripping of the chips, chip break, uneven brightness of the display effect etc.

Currently, the warping problem of the chip and substrate is addressed by using low-temperature anisotropic conductive adhesive products, which, however, are expensive and also technically immature at present.

### SUMMARY

The embodiment of present invention provides an apparatus and method for bonding chips, which can overcome the warping problem of the bonded chips and substrate greatly.

The first aspect of the present invention provides an apparatus for bonding chips, comprising a base stage and a press head,

The side of the base stage for carrying the substrates comprises a first downward concave curvature, the side of the press head contacting with the chips comprises a second downward convex curvature, and the base stage with the first curvature and the press head with the second curvature match with each other.

For example, the first curvature and second curvature have a same curvature radius.

For example, the tangential direction of the edge of the first curvature forms an angle of 0.5°˜1.5° with respect to the horizontal plane.

For example, the bonding apparatus is used for bonding COG chips.

The second aspect of the present invention provides a method for bonding chips, comprising:

Placing a substrate onto a base stage having a first downward concave curvature;

Coating the substrate with anisotropic conductive adhesive, placing the chips onto the anisotropic conductive adhesive and pre-fixing the same;

Bonding chips onto the substrate by means of the press head having a second downward convex curvature;

Wherein, the base stage having the first curvature and the press head having the second curvature match with each other.

For example, the first curvature and second curvature have a same curvature radius.

For example, the tangential direction of the edge of the first curvature forms an angle of 0.5°˜1.5° with respect to the horizontal plane.

For example, the anisotropic conductive adhesive is coated at two adjacent edge sides of the substrate.

For example, bonding chips onto the substrate by means of the press head having a second downward convex curvature comprises:

the temperature of the press head is in a range of 150° C.˜170° C.

For example, the substrate is a glass substrate.

For example, the bonding method is a method for COG chip bonding.

### BRIEF DESCRIPTION OF THE DRAWINGS

In order to describe more clearly the technical solution of the embodiment of present invention, the drawings required for showing the embodiments will be described briefly in the following. Obviously, the drawings in the following description are just some of the embodiments of the present invention, and do not tend to limit the present invention.

FIG. 1 is a structural schematic view of the apparatus for bonding chips according to an embodiment of present invention;

FIG. 2 is a schematic view of the apparatus for bonding chips according to the embodiment of present invention;

FIG. 3 is a schematic view showing the deformation of the chips and substrate during the primary pressing according to the embodiment of present invention;

FIG. 4 is a schematic view showing the deformation of the chips and substrate after the cooling according to the embodiment of present invention;

FIG. 5 is a schematic view illustrating the test result according to the embodiment of present invention;

FIG. 6 is a schematic view showing the flow chart of the method for bonding chips according to the embodiment of present invention.

### REFERENCE NUMERALS

1—base stage; 2—press head; 3—substrate; 4—-chip; 5—anisotropic conductive adhesive.

### DETAILED DESCRIPTION

A clear and complete description about the technical solution of the embodiment of present invention will be made in the following in conjunction with the drawings of the embodiment of present invention. Apparently, the described embodiments are only some embodiments of the present invention, rather than all of the embodiments. Based on the described embodiments of present invention, all the other embodiments attained by the skilled in this art without any creative endeavor fall within the protection scope of the present invention.

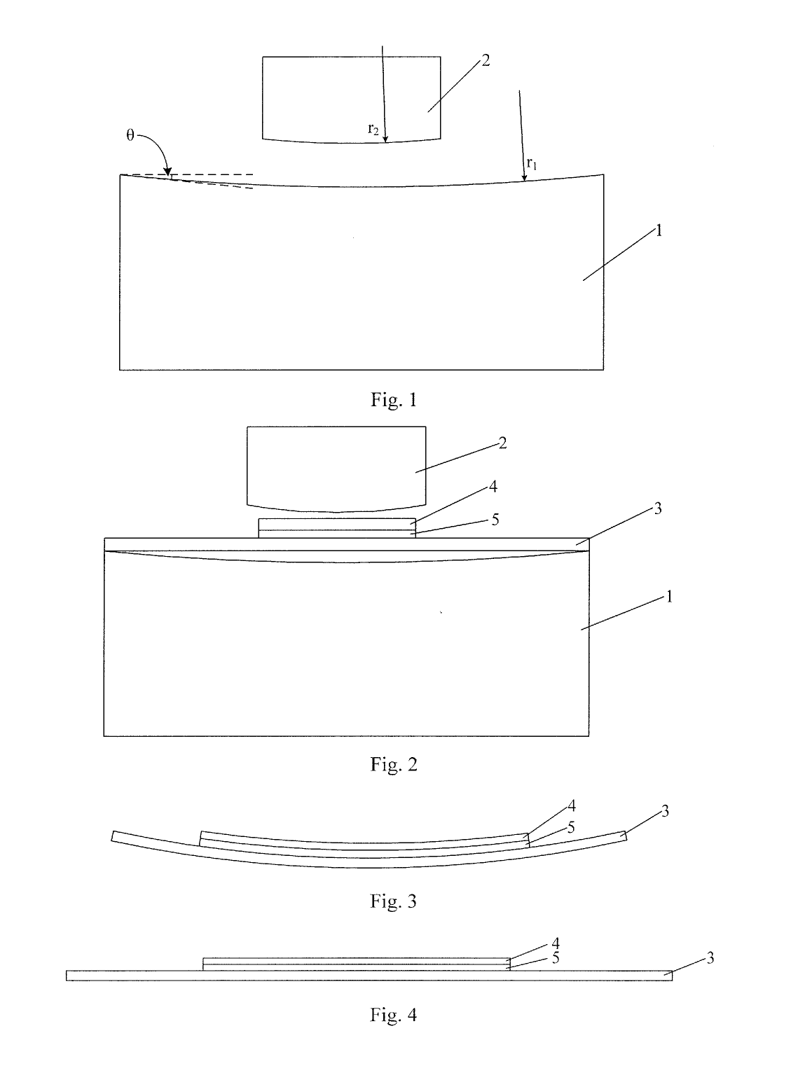

An embodiment of present invention provides an apparatus for bonding chips, comprising a base stage 1 and a press head 2, as shown in FIG. 1.

The side of the base stage 1 for carrying the substrates has a first downward concave curvature, the side of the press head 2 contacting with the chips has a second downward convex curvature, and the base stage 1 with the first curvature and the press head 2 with the second curvature match with each other.

As shown in FIG. 1, the first downward concave curvature of the base stage 1 has a radius r1, and the second downward convex curvature of the press head 2 has a radius of r2. When the base stage 1 and the press head 2 are used for the chip bonding process, the base stage 1 and the press head 2 match with each other, as shown in FIG. 2. Because the substrate 3 and the chip 4 have certain resilience, especially, the chip 4 has certain ductibility, the substrate 3 and the chip 4 will have a downwardly bending curvature during the primary pressing process of the base stage 1 and the press head 2, as shown in FIG. 3. Because the chip 4 has a greater contraction dimension than the substrate during the cooling process of the chip 4 and the substrate 3, the downwardly bending substrate 3 and the chip 4 deform toward the centre of the arc during the cooling process, and thus the chip 4 and the substrate 3 after the cooling become more flat, as shown in FIG. 4. The embodiment of present invention substantially decreases the stress between the chip 4 and the substrate 3, prevents the chip 4 and the substrate 3 from warping, and thus prevents the chip 4 from stripping, the chip 4 break, and uneven brightness of the display effect and similar adverse results.

As shown in FIGS. 2-4, there is a layer of anisotropic conductive adhesive 5 between the chip 4 and the substrate 3. The anisotropic conductive adhesive 5 mainly comprises two major components, i.e., resin adhesive and conductive particles. In addition to moisture proof, adhesive, heat resistant, and insulating, the resin adhesive mainly functions to bond the chip 4 onto the substrate 3, fixing the relative position between he chip 4 and the substrate 3, and provide compressing force to maintain the contact area between the electrodes and the conductive particles.

In some embodiments of the present invention, the side of the base stage 1 for carrying the substrate 3 has a dimension and shape substantially corresponding to those of the substrate 3. For example, the side of the base stage 1 for carrying the substrate 3 has a dimension equal to or slightly larger than that of the substrate 3. For example, as shown in FIG. 2, during the bonding process of the embodiment of present invention, when the substrate 3 is positioned on the base stage 1, the edges of the base stage 1 substantially align with the edges of the substrate 3.

For example, in order to improve the match level between the base stage 1 and the press head 2, the first curvature may have a same curvature radius as that of the second curvature, that is, r1=r2. For example, in order to avoid undesirable results such as the break of the chip 4 and the substrate 3 during the primary pressing, the first curvature may have tangential directions at the edges which normally have an angle θ in a range of 0.5°˜1.5° with respect to the horizontal plane. For example, the value of the angle θ between the tangential direction at the edge of the first curvature and the horizontal plane should be determined based on the dimension of the substrate. The influence of the angles θ for substrates of normal dimensions is listed in the following table.

| substrate | θ | | | | | | | | | |
|---|---|---|---|---|---|---|---|---|---|---|
| dimension | 0.25° | 0.50° | 0.75° | 1.00° | 1.25° | 1.50° | 1.75° | 2.00° | 2.25° | 2.50° |
| 4.3″ | L1 | L0 | L1 | L2 | broken | — | — | — | — | — |
| 6.0″ | L3 | L2 | L0 | L1 | L2 | broken | — | — | — | — |
| 10.1″ | L3 | L2 | L1 | L0 | L0 | L1 | L2 | L3 | broken | |
| 14.0″ | L3 | L3 | L2 | L2 | L1 | L0 | L1 | L2 | L3 | broken |

In the above table, L0˜L3 represent the degree of the undesirable effect occurred in the substrates, wherein L0 refers to a least undesirable effect, L0˜L3 refer to successively increased undesirable effects, and L3 refers to the most undesirable effect.

From the above table, there is a most favorable value for the angle θ for the substrate of each dimension. Generally, the substrate 3 having such dimension and the chip 4 are bonded together by a base stage 1 and a press head 2 having a curvature corresponding to the most favorable angle. Flatness test is made to the cooled substrate 3 and chip 4, that is, the warping degree of the bonded chip 4 is tested. The warping degree is measured by continuously testing the height of the bonded chip surface to be tested with a non-contact probe, so as to obtain a continuous curve, in which the height difference between the highest point and the lowest point of the curve represents the warping degree. Typically, a larger height difference represents a larger warping degree of the chip 4; and on the contrary, a smaller height difference represents a lower warping degree of the chip 4.

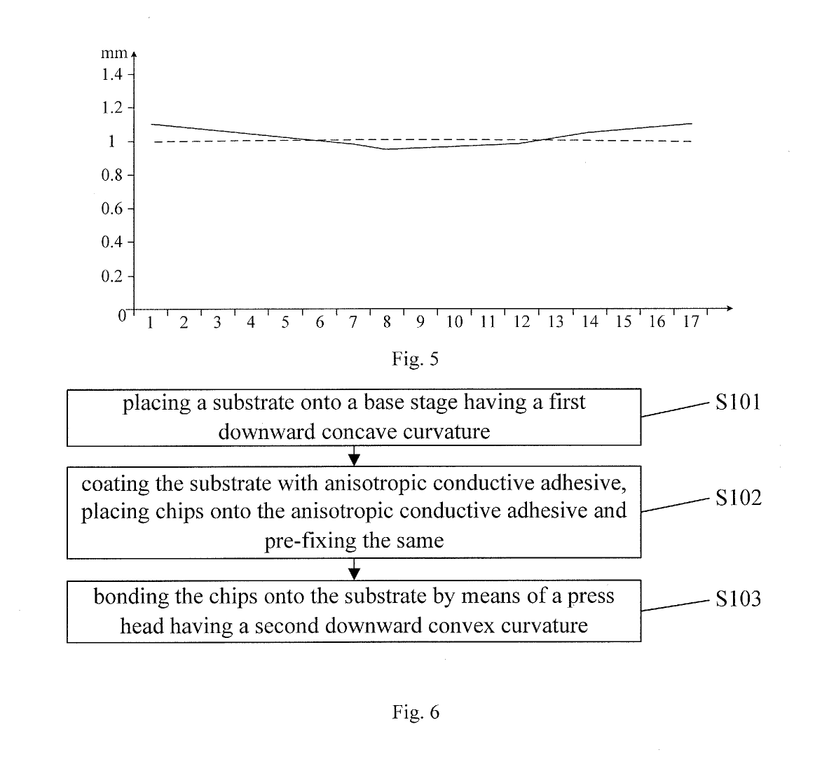

In the embodiments of present invention, as shown in FIG. 5, the substrate 3 and the chip 4 are arranged in an approximately horizontal state during the front side testing (i.e., the chip 4 is located on the substrate 3, and the non-contact probe performs the measurement from above). At this time, the difference between the highest point and the lowest point is only 0.01 mm (see the dashed line in FIG. 5). During the reverse side testing (i.e., the chip 4 is arranged under the substrate 3, and the non-contact probe performs the measurement through the substrate from above), the difference between the highest point and the lowest point is 0.15 mm (see the solid line in FIG. 5). As to the substrate 3 and the chip 4 provided by the embodiment of present invention, the influence of gravity is relative small. Thus, it can be understood that the chip bonding apparatus provided by the embodiment of present invention can greatly reduce the stress the two ends of the chip 4 acting upon the substrate 3, and thus effectively prevent the warping of the chip and the substrate.

In the technical solution of this embodiment, the base stage of the apparatus for bonding chips comprises a first downward concave curvature, and the press head comprises a second downward convex curvature, and the base stage having the first curvature and the press head having the second curvature match with each other. During the primary pressing of the chip and the substrate by the base stage and the press head so as to bond the chip onto the substrate, both of the chips and the substrate have a downwardly bending curvature. In the cooling process of the chips and the substrate, since the chip has a greater contraction dimension than the substrate, the downwardly bending substrate and chip deform toward the circle centre of the arc during the cooling process. After the cooling process, the chips and substrate become relatively flat, so that the stress between the chips and the substrate is greatly reduced. Thus, it is capable of preventing the warping of the chip and substrate, and then preventing the occurrence of the break of the chip glass and the chip, uneven brightness of the display effect and similar undesirable result.

Furthermore, the embodiments of present invention also provide a method for bonding chips utilizing the above apparatus for bonding the chips, in particular as shown in FIG. 6, the method comprises:

Step S101: placing the substrate onto the base stage having the first downward concave curvature;

Step S102: coating the substrate with anisotropic conductive adhesive, placing the chips onto the anisotropic conductive adhesive and pre-fixing the same;

Step S103: bonding the chips onto the substrate by using the press head having a second downward convex curvature;

The base stage having the first curvature and the press head having the second curvature match with each other.

For example, in order to improve the match level of the base stage 1 and the press head 2, the first and second curvatures have a same curvature radius.

For example, in order to prevent the breakage of the substrate 3 during the primary pressing process, the tangential direction of the edge of the first curvature forms an angle of 0.5°˜1.5° with respect to the horizontal plane.

For example, since the chip 4 is normally provided at two adjacent edge sides of the substrate, the anisotropic conductive adhesive 5 is coated at the two adjacent edge sides of the substrate 3.

Generally, a temperature of 150° C.˜170° C. is required for the anisotropic conductive adhesive 5 to melt the resin adhesive contained therein to perform the bonding process. In the step S103, the temperature for the press head 2 is preferably between 150° C. and 170° C. In other embodiments of the present invention, the temperature of the press head 2 can be selected based on the suitable temperature of the anisotropic conductive adhesive 5.

For example, the substrate 3 is a glass substrate. In other embodiments of the present invention, the substrate 3 may also be transparent materials, such as plastic.

The above are only specific embodiments of the present invention, the protective scope of the present invention is not restricted thereto, and any skilled person in this art may readily conceive alterations or modifications within the technical scope disclosed in the present invention, all of which are encompassed within the protective scope of the present invention. Hence, the protective scope of the present invention should be defined by the appended claims.

What is claimed is:

1. An apparatus for bonding chips, comprising a base stage and a press head, wherein,
the side of the base stage for carrying the substrates comprises a first downward concave curvature, the side of the press head contacting with the chips comprises a second downward convex curvature, and the base stage having the first curvature and the press head having the second curvature match with each other.

2. The apparatus for bonding the chips according to claim 1, wherein,
the first curvature and second curvature have a same curvature radius.

3. The apparatus for bonding the chips according to claim 1, wherein,
the tangential direction of the edges of the first curvature forms an angle of 0.5°˜1.5° with respect to the horizontal plane.

4. The apparatus for bonding the chips according to claim 1, wherein,
the bonding apparatus is used for COG chip bonding.

5. A method for bonding chips, comprising:
placing a substrate onto a base stage having a first downward concave curvature;
coating the substrate with anisotropic conductive adhesive, placing the chips onto the anisotropic conductive adhesive and pre-fixing the same;
bonding the chips onto the substrate by means of a press head having a second downward convex curvature;
wherein, the base stage having the first curvature and the press head having the second curvature match with each other.

6. The method for bonding chips according to claim 5, wherein,
the first curvature and second curvature have a same curvature radius.

7. The method for bonding chips according to claim 5, wherein,
the tangential direction of the edge of the first curvature forms an angle of 0.5°˜1.5° with respect to the horizontal plane.

8. The method for bonding chips according to claim 5, wherein,
the anisotropic conductive adhesive is coated at two adjacent edge sides of the substrate.

9. The method for bonding chips according to claim 5, wherein, bonding the chips onto the substrate by means of the press head having a second downward convex curvature comprises:
the temperature of the press head is in a range of 150° C.˜170° C.

10. The method for bonding chips according to claim 5, wherein,
the substrate is a glass substrate.

11. The method for bonding chips according to claim 5, wherein,
the bonding method is a method for COG chip bonding.
